(19) United States
(12) Patent Application Publication
(10) Pub. No.: US 2005/0186732 A1
(43) Pub. Date: Aug. 25, 2005

(54) Semiconductor devices having plug contact holes extending downward from a main surface of a semiconductor substrate and methods of forming the same

(76) Inventor: Cheol-Ju Yun, Gyeonggi-do (KR)

Correspondence Address: MARGER JOHNSON & MCCOLLOM, P.C., 1030 SW MORRISON STREET, PORTLAND, OR, 97205, US

(21) Appl. No.: 11/066,842

(22) Filed: Feb. 23, 2005

(30) Foreign Application Priority Data
Feb. 24, 2004 (KR) 2004-12399

(51) Int. Cl. H01L 21/8242; H01L 21/20

(52) U.S. Cl. 438/253; 438/396; 257/306

(57) ABSTRACT

According to some embodiments of the invention, semiconductor devices and DRAM cells have plug contact holes. Methods of forming the same include forming a channel-portion hole disposed in a semiconductor substrate. Lower portions of the plug contact holes between first and second word line patterns extend downward from the main surface of the semiconductor substrate, thereby reducing a contact resistance between plug patterns and electrode impurity regions. The DRAM cell having the plug contact holes can improve the current driving capability of a transistor and the refresh characteristics of a capacitor.

### CROSS-REFERENCE TO RELATED APPLICATION

This patent application claims priority from Korean Patent Application No. 10-2004-0012399, filed Feb. 24, 2004, the contents of which are hereby incorporated by reference in their entirety.

### BACKGROUND OF INVENTION

1. Technical Field

The invention relates to semiconductor devices and methods of forming the same, and more particularly, to semiconductor devices having plug contact holes extending downward from a main surface of a semiconductor substrate; and methods of forming the same.

2. Discussion of the Related Art

Generally, a semiconductor device has individual elements to transfer user data to a desired position therein. The individual elements include a resistor, a capacitor, a transistor and so on.

The transistor includes a word line pattern, source/drain regions, and a channel region. At this time, the channel region is disposed in a semiconductor substrate under the word line pattern, and the source/drain regions are formed in the semiconductor substrate while overlapping the word line pattern. Further, the word line pattern is disposed on the semiconductor substrate. If a voltage is applied to the word line pattern to reverse the conductivity type of the channel region, the channel region functions to connect the source and the drain regions, thereby serving as a route allowing charges to be moved.

As a design rule of a semiconductor device is reduced, the channel region, as well as the word line pattern is reduced in size in the semiconductor substrate. To cope with this size reduction, the semiconductor device includes a channel-portion hole having a trench shape in the semiconductor substrate and a word line pattern filling the channel-portion hole. The word line pattern provides a channel region along the semiconductor substrate defining the channel-portion hole. That is, the word line can provide the channel region to prevent deteriorating electrical characteristics of the transistor even though the design rule is reduced.

However, the transistor includes electrical nodes (hereinafter, referred to as “plug patterns”), which contact the semiconductor substrate, at both sides of the word line pattern. The plug patterns have an increased contact resistance with the reduction of the design rule of the semiconductor device. This is because the reduction of the design rule decreases contact areas between the plug patterns and the semiconductor substrate. The plug patterns may be electrical nodes of a capacitor and a bit line, respectively. The plug patterns can interrupt the flow of the charges introduced from a transistor due to the increased contact resistance, thereby deteriorating the electrical characteristics of the semiconductor device.

The above situation is addressed in U.S. Pat. No. 6,570,233 to Akira Matsumura (the '233 patent) discloses methods of fabricating an integrated circuit.

According to the '233 patent, the method includes: providing a semiconductor substrate; a transistor is formed on the semiconductor substrate. The transistor has a gate that controls a current as well as source and drain regions. An insulating layer is formed over the transistor, and a contact hole is formed in the insulating layer. A first layer, which lines the contact hole and is formed of a conductive material, having a dopant of a first concentration, is formed on one of the source and the drain regions.

Further, the method includes forming a second layer, which lines the first layer and is formed of a conductive material having a dopant of a second concentration. A contact plug is formed of the first layer and the second layer, and the first concentration is higher than the second concentration. The first layer is formed after implanting ions in at least one of the source and the drain regions with a first energy level, and the second layer is formed after implanting ions through the first layer with a second energy level higher than the first energy level to form the contact plug. Thus, the contact resistance between the contact plug and the semiconductor substrate can be reduced by the method.

However, the method may cause a short channel effect in the transistor due to an implantation process occurring twice, and the presence of the contact plug. This is because the ions from both implantation processes and the dopants of the first and the second layers may be deeply diffused to the channel of the transistor.

### SUMMARY OF THE INVENTION

According to some embodiments of the invention, semiconductor devices and DRAM cells have plug contact holes that extend downward from a main surface of a semiconductor substrate suitable for reducing the contact resistance of a semiconductor substrate and plug patterns.

And embodiments of the invention also include methods of forming semiconductor devices and DRAM cells having plug contact holes that extend downward from a main surface of a semiconductor substrate capable of reducing the contact resistance of a semiconductor substrate and plug patterns.

### BRIEF DESCRIPTION OF THE DRAWINGS

Exemplary embodiments of the invention will be readily apparent to those of ordinary skill in the art upon review of the detailed description that follows when taken in conjunction with the accompanying drawings, in which like reference numerals denote like parts.

FIG. 1 is a layout of a DRAM cell according to an embodiment of the invention;

FIG. 2 is a sectional view of a DRAM cell taken along line I-I′ of FIG. 1; and

FIGS. 3 through 19 are sectional views illustrating a method of forming a DRAM cell taken along line I-I′ of FIG. 1, respectively.

### DETAILED DESCRIPTION OF THE INVENTION

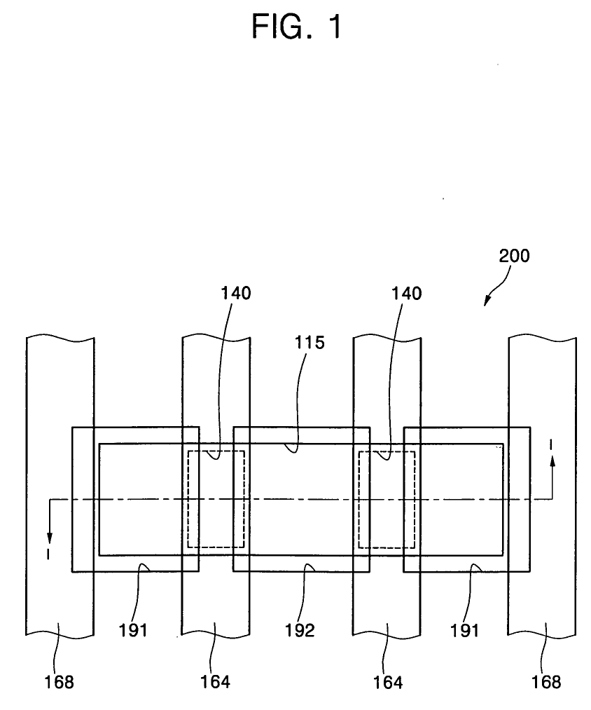

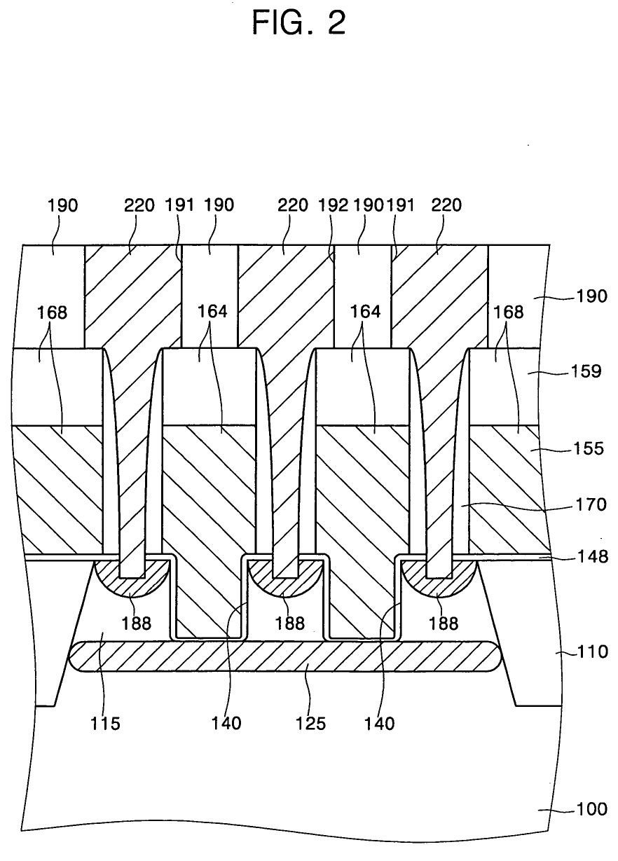

FIG. 1 is a layout of a DRAM cell according to an embodiment of the invention, and FIG. 2 is a sectional view of a DRAM cell taken along line I-I′ of FIG. 1.

Referring to FIGS. 1 and 2, a device isolation layer 110 is disposed in a semiconductor substrate 100 of a DRAM cell array region 200, and the device isolation layer 110 defines an active region 115. The semiconductor substrate 100 preferably has a P conductivity type, but the semiconductor substrate 100 may have an N conductivity type.

Channel-portion holes 140 are disposed in the semiconductor substrate 100 of the active region 115, and the channel-portion holes 140 have a trench shape. A channel region 125 is disposed under the channel-portion holes 140 and the channel region 125 contacts the channel-portion holes 140. The channel region 125 and the semiconductor substrate 100 have a same conductivity type. In a peripheral circuit region except for the DRAM cell array region 200, the channel region 125 and the semiconductor substrate 100 may have a same conductivity type, or may have different conductivity types from each other.

First and second word line patterns 164, 168 are disposed on the active region 115 and the device isolation layer 110, respectively. Each of the first and the second word line patterns 164, 168 includes a word line 155 and a word line capping layer pattern 159 stacked thereon. The second word line patterns 168, which are on the device isolation layer 110, are disposed in parallel and opposite to at least one of the first word line patterns 164. The word lines 155 of the first word line patterns 164 are formed to fill the channel-portion holes 140 in the active region 115, respectively. Each of the word lines 155 includes a polysilicon layer having an N or a P conductivity type, and a metal silicide layer stacked thereon. Alternatively, the word line 155 may be the polysilicon layer having an N or a P conductivity type. The polysilicon layer preferably has a conductivity type opposite to that of the channel region 125. In the peripheral circuit region except for the DRAM cell array region 200, the polysilicon layer and the channel region 125 may have a same conductivity type, or different conductivity types from each other. The word line capping layer pattern 159 is preferably a silicon nitride (Si₃N₄).

Word line spacers 170 are disposed on sidewalls of the first and the second word line patterns 164, 168. Word line insulating layer patterns 148 are preferably disposed under the word line spacers 170 as well as under the first and the second word line patterns 164, 168, respectively. The word line spacers 170 are preferably an insulating layer having the same etching ratio as the word line capping layer pattern 159. The word line insulating layer patterns 148 are an insulating layer having an etching ratio different from the word line capping layer pattern 159, and the word line insulating layer patterns 148 are preferably one selected from a silicon oxide (SiₓO_{y}) and a silicon oxynitride (SiₓO_{y}N_{z}).

Electrode impurity regions 188 are disposed between the first and the second word line patterns 164, 168 respectively, and the electrode impurity regions 188 overlap the first and the second word line patterns 164, 168. The electrode impurity regions 188 have a different conductivity type from the channel region 125 that surrounds lower portions of the channel-portion holes 140, and the electrode impurity regions 188 refer to source and drain regions in a transistor, respectively.

Plug contact holes 191, 192 are disposed between the first and the second word line patterns 164, 168, respectively, and extend from the upper surfaces of the first and the second word line patterns 164, 168, and are isolated by an interlayer insulating layer 190. The plug contact holes 191, 192 extend downward from the main surface of the semiconductor substrate 100 so that lower portions of the plug contact holes 191, 192 are aligned in parallel with the channel-portion holes 140. The plug contact holes 191, 192 preferably have a same depth. Alternatively, the plug contact holes 191, 192 may have different depths from each other. Further, at least one of the plug contact holes 191, 192 may be aligned to expose the main surface of the semiconductor substrate 100, whereas the rest of the plug contact holes 191, 192 may extend downward from the main surface of the semiconductor substrate 100 to be aligned in parallel with the channel-portion holes 140.

The plug contact holes 191, 192 are filled with plug patterns 220, respectively. Upper portions of the plug patterns 220 are surrounded by the interlayer insulating layer 190, whereas lower portions of the plug patterns 220 are spaced apart from the first word line patterns 164 so that they are electrically isolated from each other. Further, the plug patterns 220 contact the electrode impurity regions 188, respectively. The plug patterns 220 have the same conductivity type as the electrode impurity regions 188. The plug pattern 220 filling one hole 192 of the plug contact holes is a bit line node, and the plug patterns 220 filling the other plug contact holes 191 are capacitor nodes, respectively.

Hereinafter, embodiments of the methods of forming semiconductor devices and DRAM cells according to the invention will be described in reference to attached drawings.

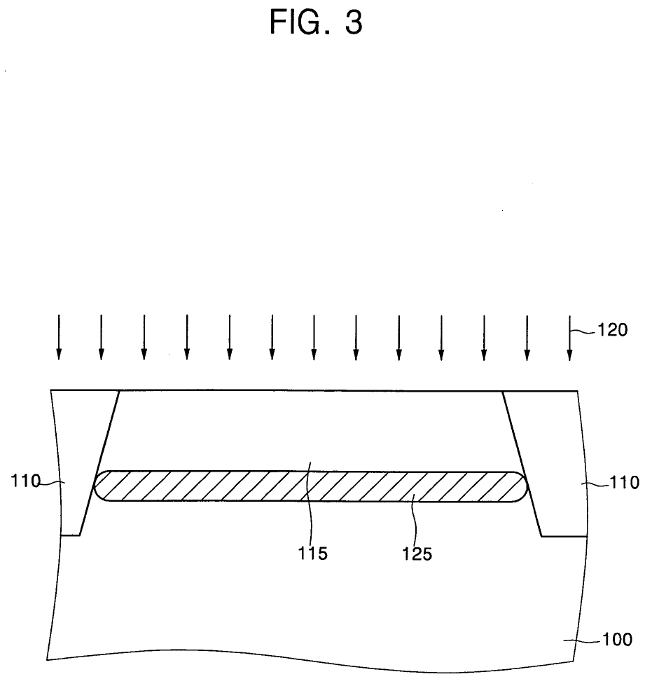

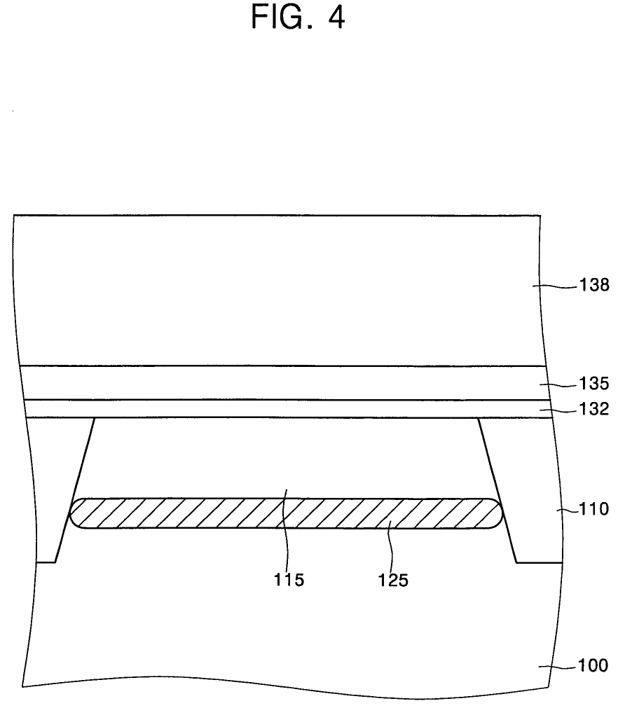

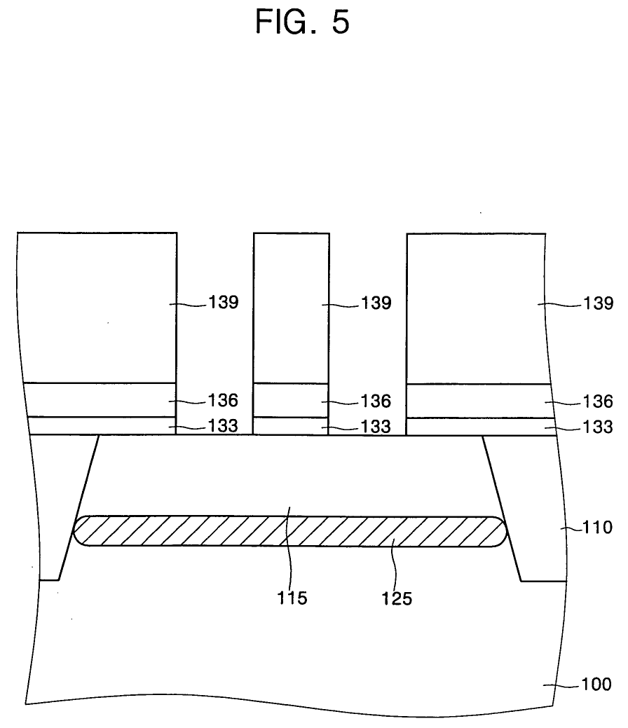

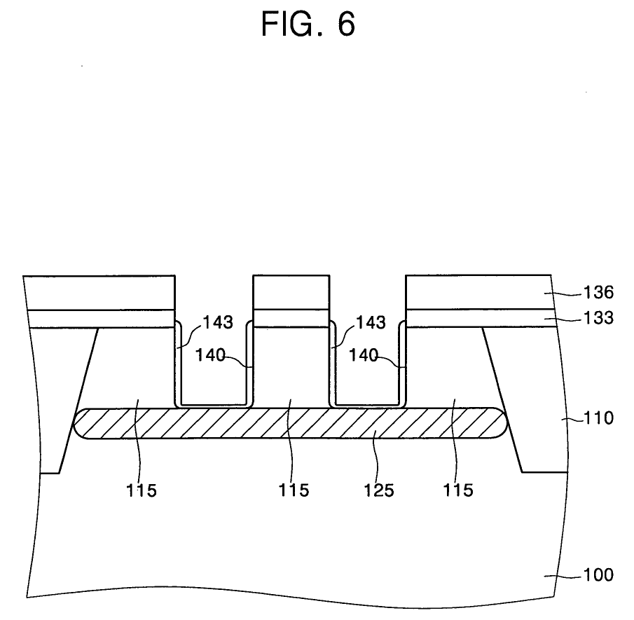

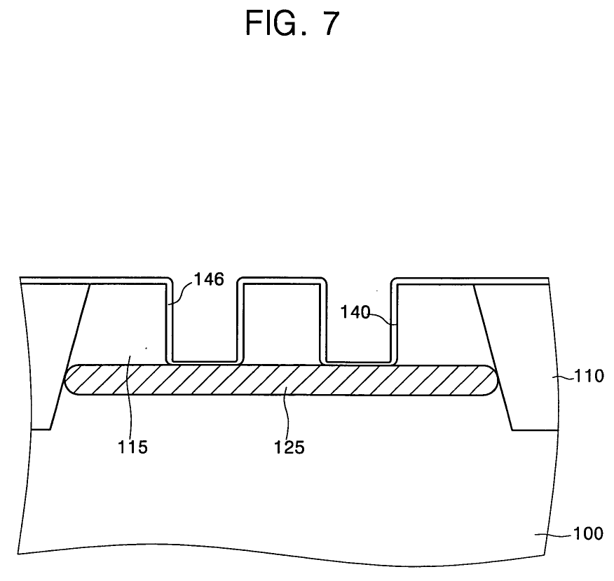

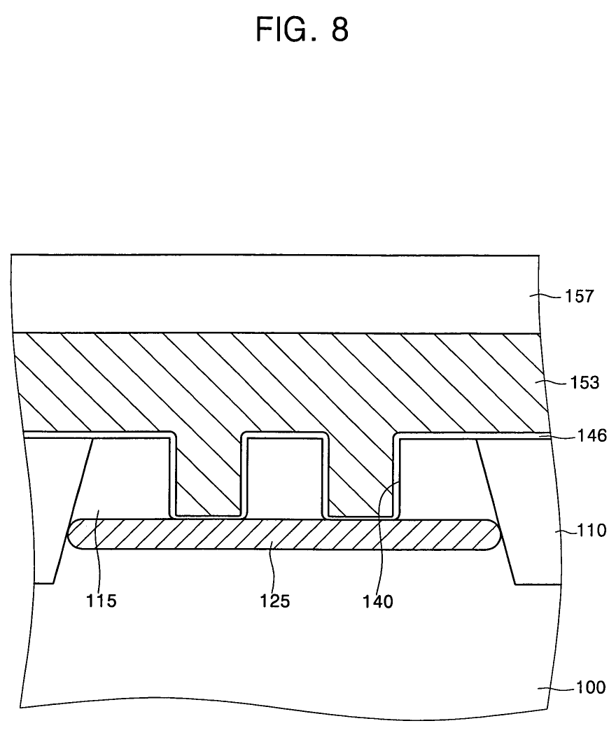

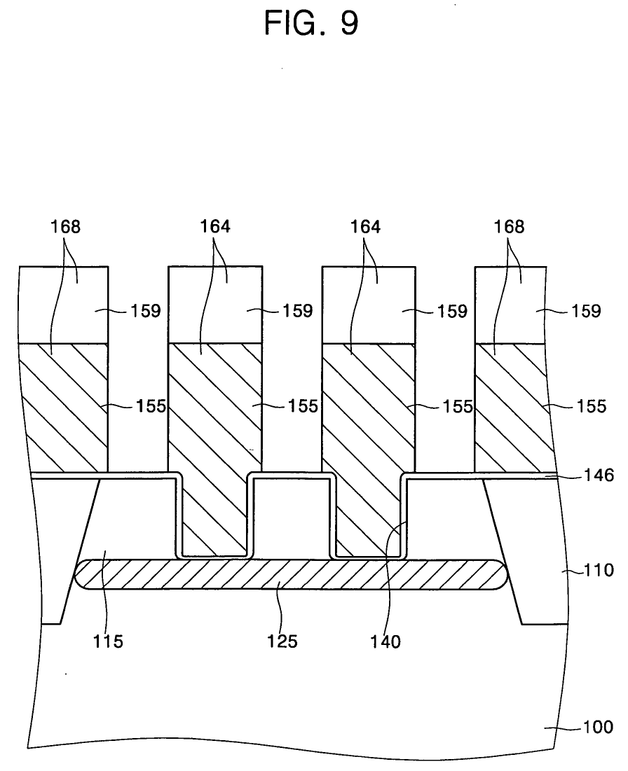

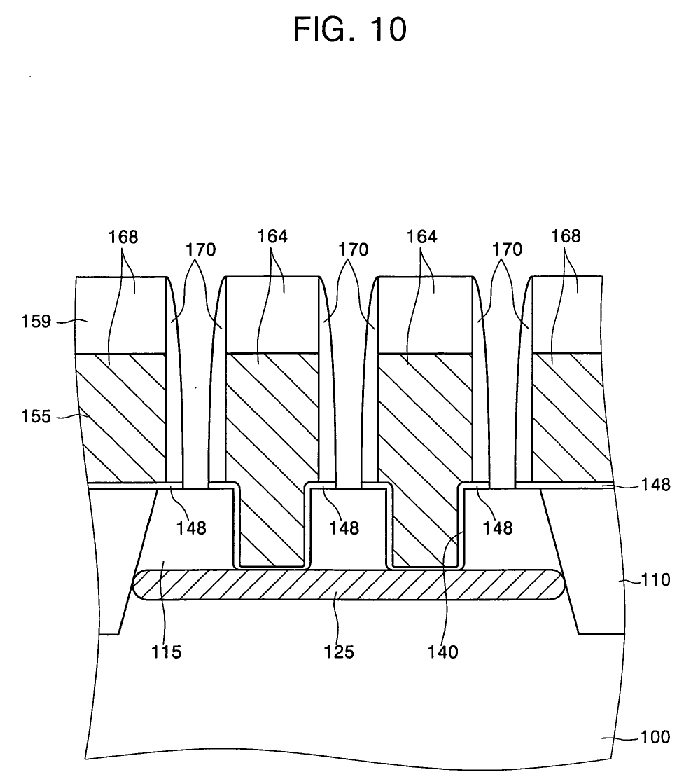

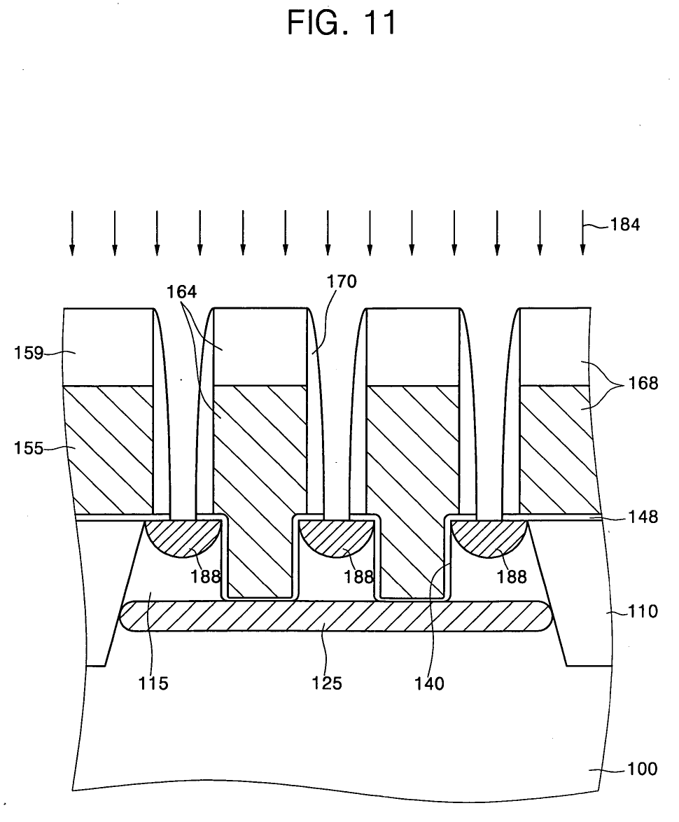

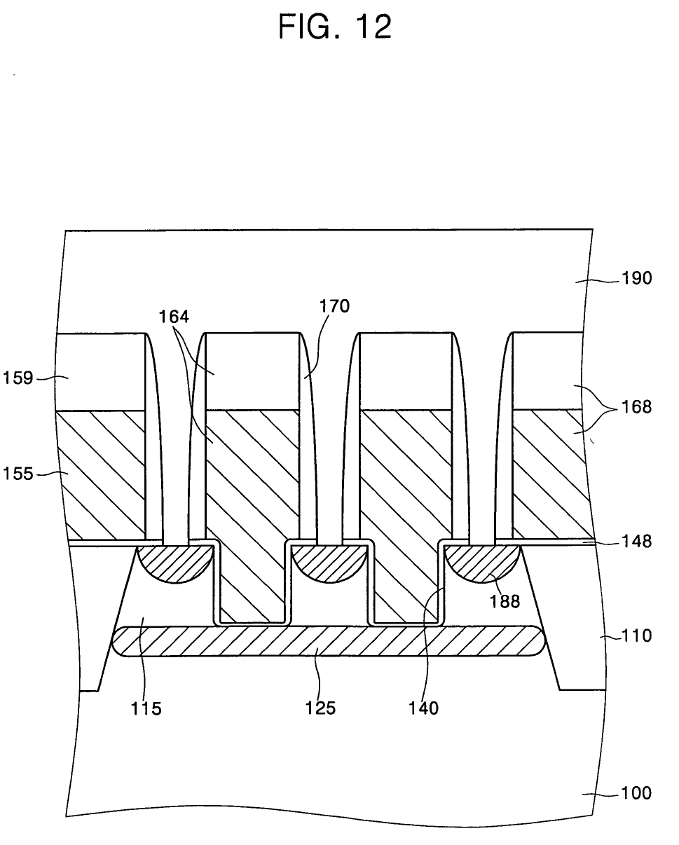

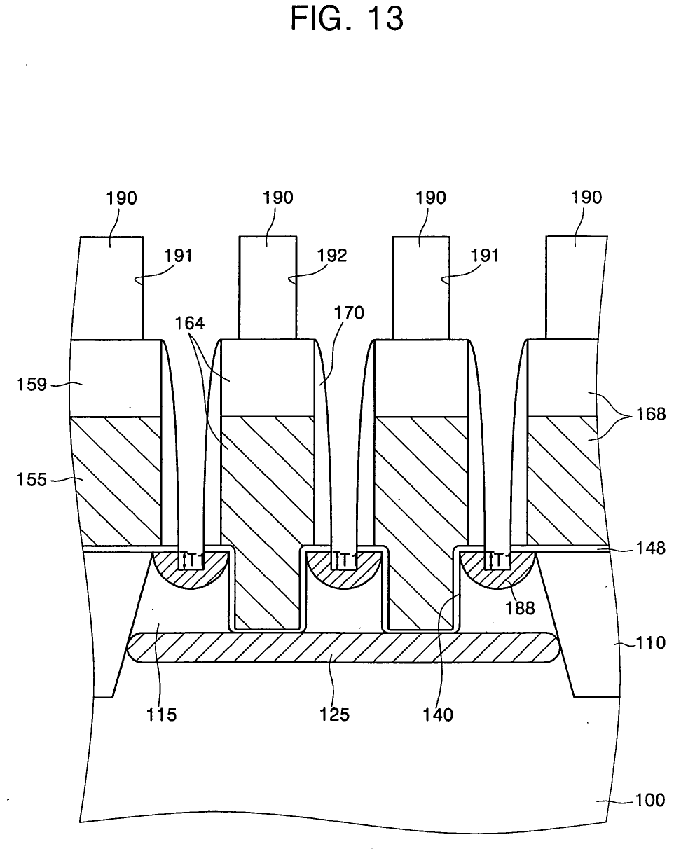

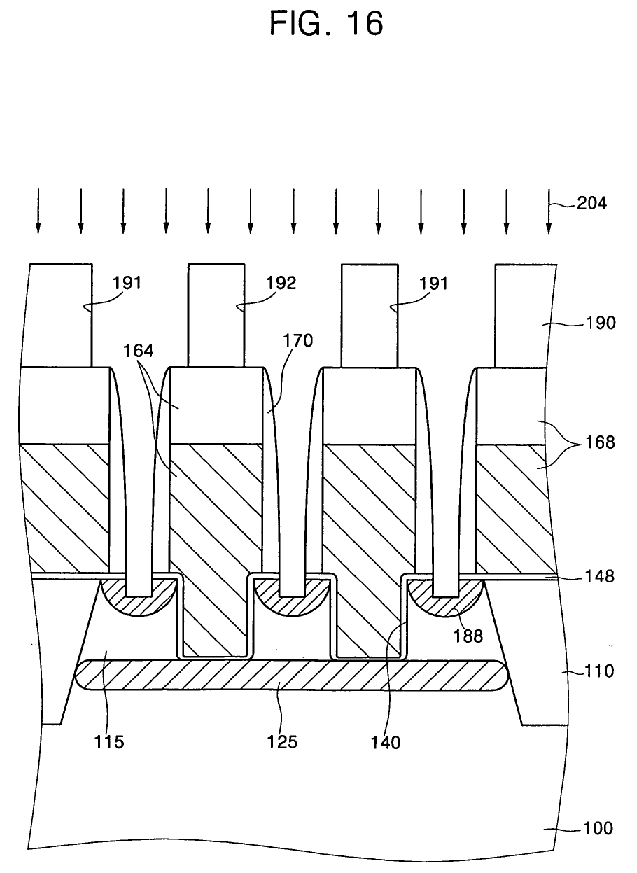

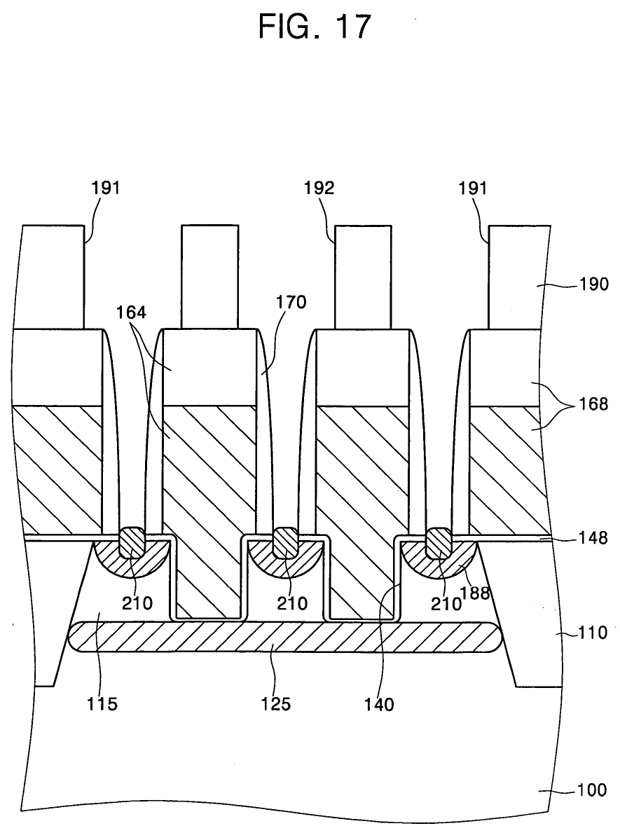

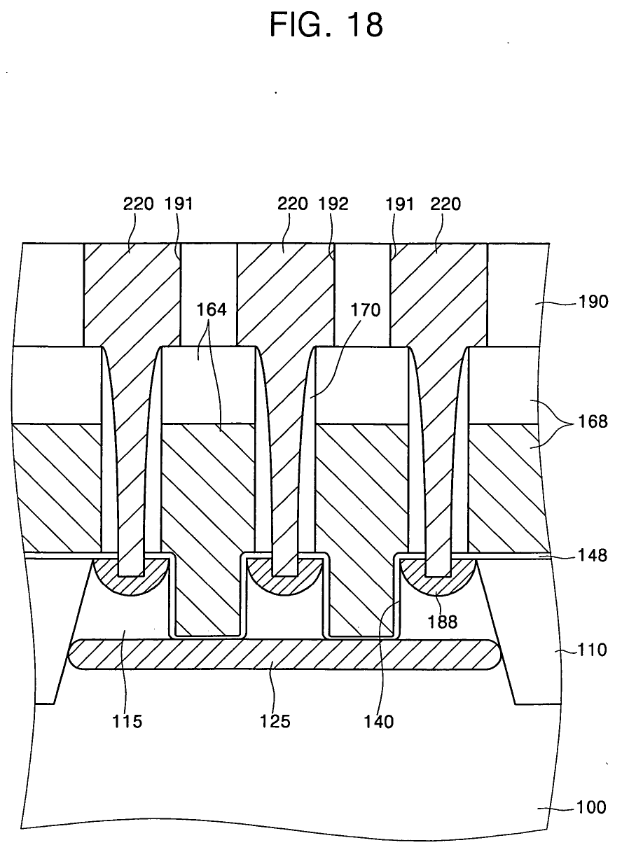

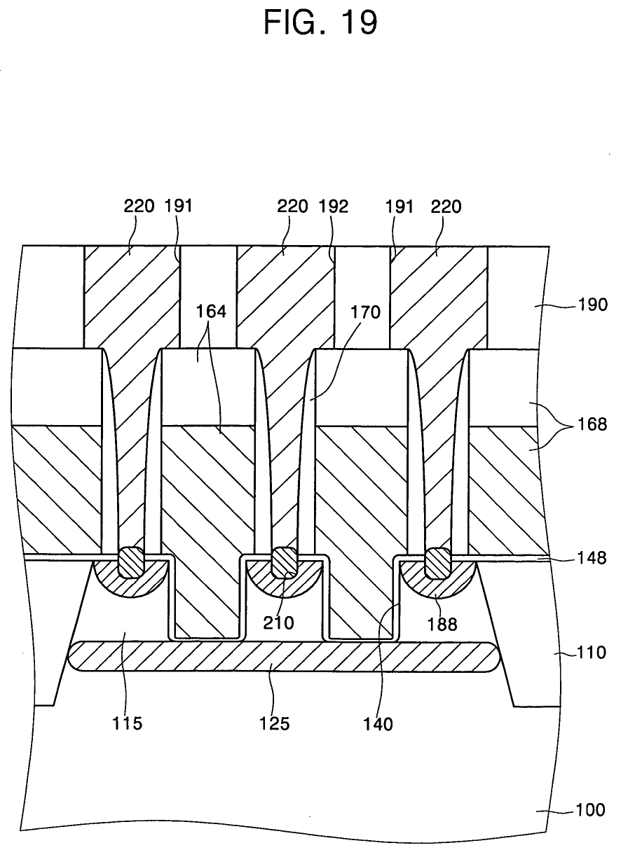

FIGS. 3 through 19 are sectional views illustrating a method of forming a DRAM cell taken along line of I-I′ of FIG. 1, respectively.

Referring to FIG. 1 and FIGS. 3 through 5, a device isolation layer 110 is formed in the semiconductor substrate 100 of the DRAM cell array region 200, and is formed to isolate the active region 115. An ion implantation process 120 is performed in the semiconductor substrate 100 by using the device isolation layer 110 as a mask, thereby forming a channel region 125. The semiconductor substrate 100 preferably has a P conductivity type, but may be formed to have an N conductivity type. The channel region 125 and the semiconductor substrate 100 are preferably formed to have the same conductivity type. Further, if the channel region 125 is formed in the peripheral circuit region except for the DRAM cell array region 200, the channel region 125 may have a different conductivity type from the semiconductor substrate 100, or may have the same conductivity type as the semiconductor substrate 100.

A pad layer 132, a reflective layer 135, and a photoresist layer 138 are sequentially formed on the semiconductor substrate having the device isolation layer 110. The reflective layer 135 may not be formed on the semiconductor substrate 100 if fine photoresist patterns can be formed through a photolithography process.

Photoresist patterns 139 are formed on the reflective layer 135 by performing the photolithography process on the photoresist layer 138, and an etching process is sequentially performed in the reflective layer 135 and the pad layer 132 by using the photoresist patterns 139 as an etching mask to expose a main surface of the semiconductor substrate 100 of the active region 115. The etching process forms a pad layer pattern 133 and a reflective layer pattern 136 stacked thereon.

Referring to FIG. 1 and FIGS. 6 through 8, using the pad layer patterns 133, as well as the photoresist patterns 139 and the reflective layer patterns 136 as an etching mask, an etching process is performed in the semiconductor substrate 100. The etching process forms channel-portion holes 140 extending downward from the main surface of the semiconductor substrate 100 to a predetermined depth. The channel-portion holes 140 are formed in the active region 115 surrounded by a device isolation layer 110. The channel-portion holes 140 are formed to contact the channel region 125. After forming the channel-portion holes 140, photoresist patterns 139 are removed from the semiconductor substrate 100.

By using the pad layer patterns 136 and the reflective layer patterns 133 as an oxidation barrier layer, an oxidation process is performed on the semiconductor substrate 100. The oxidation process forms sacrificial layers 143 respectively on the channel-portion holes 140. The sacrificial layers 143 function to stabilize the state of the interface of the semiconductor substrate 100, and the sacrificial layers 143 are preferably formed of an oxide (SiO₂).

The sacrificial layers 143, along with the pad layer patterns 136 and the reflective layer patterns 133, are sequentially removed from the semiconductor substrate 100, and a word line capping layer 157 along with a word line insulating layer 146 and a word line layer 153 are formed on the semiconductor substrate having the channel-portion holes 140. The word line insulating layer 146 is conformably formed on the channel-portion holes 140 to cover the main surface of the semiconductor substrate 100. The word line layer 153 is preferably formed using a polysilicon layer having an N or a P conductivity type and a metal silicide layer stacked thereon. Or the word line layer 153 may simply be formed of the polysilicon layer having an N or a P conductivity type. The polysilicon layer is preferably formed to have a different conductivity type from that of the channel region 125. If the polysilicon layer is formed in the peripheral circuit region except for the DRAM cell array region 200, it may be formed to have the same or different conductivity type as that of the channel region 125. Preferably, the word line insulating layer 146 is formed of oxide (SiO₂), and the word line capping layer 157 is formed of an insulating layer having an different etching ratio from the word line insulating layer 146, for example, silicon nitride (Si₃N₄).

Referring to FIG. 1 and FIGS. 9 through 11, by using the word line insulating layer 146 as an etch stop layer, a photolithographic process and an etching process are sequentially performed in the word line capping layer 157 and the word line layer 153. The photolithography and etching processes form first and second word line patterns 164, 168 on the word line insulating layer 146. Each of the first and the second word line patterns 164, 168 are formed of a word line 155 and a word line capping layer pattern 159 stacked thereon. The first word line patterns 164 are disposed on the active region 115 to be spaced apart from each other, and are formed to fill the channel-portion holes 140 respectively. The second word line patterns 168 are formed in parallel and opposite to at least one of the first word line patterns 164, and formed on the device isolation layer 110.

Word line spacers 170 are respectively formed on the sidewalls of the first and the second word line patterns 164, 168 to expose the semiconductor substrate 100. Then, word line insulating layer pattern 148 is formed under the word line spacers 170 as well as under the first and the second word line patterns 164, 168. The word line spacer 170 is preferably formed of an insulating layer having the same etching ratio as the word line capping layer pattern 159.

By using the word line spacers 170 as well as the first and the second word line patterns 164, 168 as a mask, an ion implantation process 184 is performed in the semiconductor substrate 100 to form electrode impurity regions 188. The electrode impurity regions 188 are formed to overlap the first and the second word line patterns 164, 168. Further, the electrode impurity regions 188 have a different conductivity type from the channel region 125 surrounding the lower portions of the channel-portion holes 140, and they are formed to have a dose higher than that of the channel region 125. The electrode impurity regions 188 are formed to be used as source and drain regions of a transistor, respectively.

Referring to FIG. 1 and FIGS. 12 through 15, an interlayer insulating layer 190 is formed on the semiconductor substrate having the electrode impurity regions 188, and the interlayer insulating layer 190 is formed to sufficiently cover the first and the second word line patterns 164, 168. The interlayer insulating layer 190 is formed of an insulating layer having a different etching ratio from the word line capping layer pattern 159 and the word line spacers 170.

By using the word line capping layer patterns 159 and the word line spacers 170 as an etching stop layer, an etching process is performed in the interlayer insulating layer 190 to form plug contact holes 191, 192. The plug contact holes 191, 192 are formed between the first and the second word line patterns 164, 168 to penetrate the interlayer insulating layer 190. Each of the plug contact holes 191, 192 is preferably formed so that a diameter of its upper portion is greater than that of its lower portion. The plug contact holes 191, 192 extend downward from the main surface of the semiconductor substrate 100 so that the lower portions of the plug contact holes 191, 192 are formed to be aligned in parallel with the channel-portion holes 140. The lower portions of the plug contact holes 191, 192, which extend downward from the main surface of the semiconductor substrate 100, preferably all have a same depth T1. Further, the plug contact holes 191, 192 may have different depths at their lower portions, which extend downward from the main surface of the semiconductor substrate 100. At this time, the plug contact holes 191, 192 expose the semiconductor substrate more than in the case of exposing only the main surface of the semiconductor substrate 100.

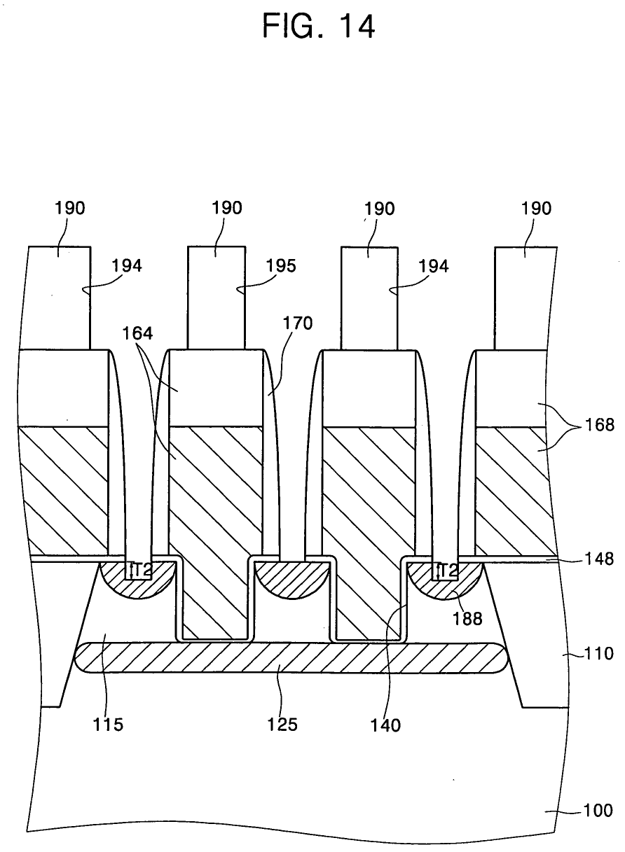

Alternatively, referring to FIG. 14, two holes 194 of plug contact holes 194, 195 may be formed to extend downward from the main surface of the semiconductor substrate 100 to be aligned in parallel with the channel-portion holes 140, and the plug contact holes 194 have a same depth T2 at their lower portions, which extend downward from the main surface of the semiconductor substrate 100. The other plug contact hole 195 is formed to expose the main surface of the semiconductor substrate 100. The two holes 194 of the plug contact holes expose the semiconductor substrate 100 more than in the case of the other plug contact hole 195.

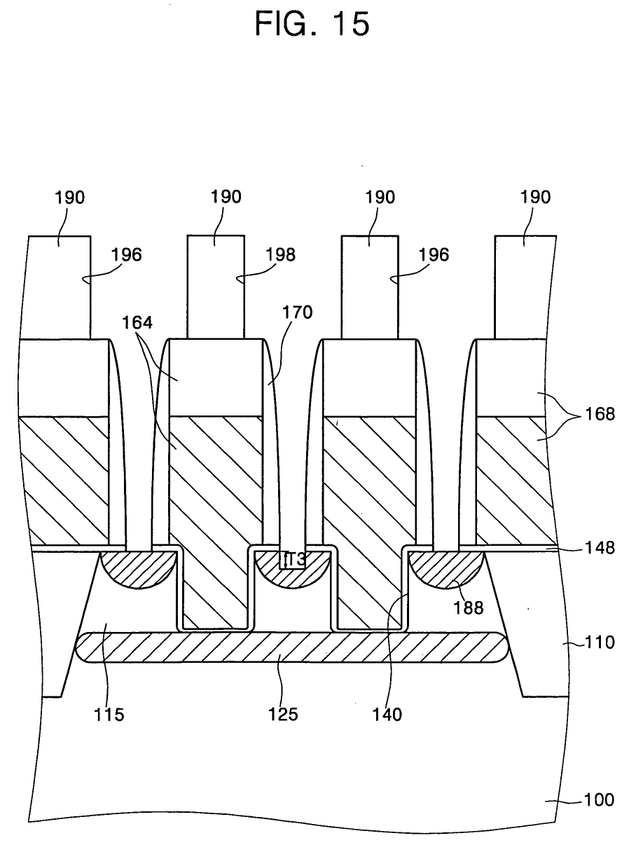

Referring to FIG. 15, plug contact holes 196, 198 may be formed in shapes different from the above. One hole 198 of the plug contact holes 196, 198 shown in FIG. 15 may be formed to extend downward from the main surface of the semiconductor substrate 100 to be aligned in parallel with the channel-portion holes 140, and the plug contact hole 198 has a predetermined depth T3 at its lower portion extending downward from the main surface of the semiconductor substrate 100. The other plug contact holes 196 are formed to expose the main surface of the semiconductor substrate 100. One hole 198 of the plug contact holes exposes the semiconductor substrate 100 more than in the case of the other plug contact holes 196.

The plug contact holes 191, 192, 194, 195, 196, 198 are formed so that their lower portions expose or are inside the electrode impurity regions 188. If the lower portions of the plug contact holes 191, 192, 194, 195, 196, 198 are formed to penetrate the electrode impurity regions 188, the plug contact holes 191, 192, 194, 195, 196, 198 may be sources of leakage current, respectively.

Referring to FIG. 1 and FIGS. 16 and 17, an ion implantation process 204 is performed in the semiconductor substrate 100 through the plug contact holes 191, 192, and the ion implantation process 204 is performed to improve characteristics of the DRAM cell.

Further, a silicide process is performed on the semiconductor substrate having the plug contact holes 191, 192, thereby forming metal silicide layers 210 respectively on the bottom of the contact holes. The metal silicide layers 210 are one selected from a titanium (Ti), a cobalt (Co), a nickel (Ni), or the like. The metal silicide layers 210 are formed not to be out of the electrode impurity region 188. If the metal silicide layers 210 are formed out of the electrode impurity regions 188, the metal silicide layers 210 may be sources of leakage current, respectively.

Referring to FIG. 1 and FIGS. 18 and 19, the plug contact holes 191, 192 are filled with plug patterns 220, respectively, and the plug patterns 220 have the same conductivity type as the electrode impurity region 188. The plug patterns 220 contact the electrode impurity regions 188, respectively. Upper portions of the plug patterns 220 are surrounded by the interlayer insulating layer 190, and lower portions thereof are formed by the first and the second word line patterns 164, 168 to be spaced apart from each other, so that they are electrically insulated from each other.

In the case that metal silicide layers 210 are formed on the bottom of the plug contact holes 191, 192, respectively, the plug patterns 220 may be formed to fill the plug contact holes 191, 192 so that they can respectively contact the electrode impurity region 188 through the metal silicide layers 210.

The plug patterns 220 may be classified by capacitor and bit-line nodes. The structures of the capacitor and the bit-line nodes can be described as follows. That is, the capacitor nodes are the plug patterns 220, which fill the plug contact holes 191 between the first and the second word line patterns 164, 168, and the bit-line nodes are the plug patterns 220, which fill the plug contact hole 192 between the first word line patterns 164.

As described above, the lower portions of the plug contact holes between the first and the second word line patterns extend downward from the main surface of the semiconductor substrate, thereby reducing a contact resistance between the plug patterns and the electrode impurity regions. The DRAM cell having the plug contact holes can improve the current driving capability of the transistor and the refresh characteristics of the capacitor. Embodiments of the invention will now be described in a non-limiting way.

Embodiments of the invention provide semiconductor devices and DRAM cells having plug contact holes extending downward from a main surface of a semiconductor substrate and methods of forming the same.

According to some embodiments of the invention, there is provided semiconductor devices having plug contact holes extending downward from a main surface of a semiconductor substrate that includes a channel-portion hole disposed in a semiconductor substrate. A word line pattern fills the channel-portion hole and is disposed on a main surface of the semiconductor substrate. Plug contact holes are disposed respectively on both sidewalls of the word line pattern. Each plug contact hole extends from an upper surface of the word line pattern and is isolated by an interlayer insulating layer. Plug patterns fill the plug contact holes, respectively. At this time, the plug contact holes extend downward from a main surface of the semiconductor substrate and are aligned in parallel with the channel-portion hole.

According to some embodiments of the invention, there is provided semiconductor devices having plug contact holes extending downward from a main surface of a semiconductor substrate that includes a channel-portion hole disposed in a semiconductor substrate. A word line pattern fills the channel-portion hole and is disposed on a main surface of the semiconductor substrate. Plug contact holes are disposed respectively on both sidewalls of the word line pattern. Each plug contact hole extends from an upper surface of the word line pattern and is isolated by an interlayer insulating layer. Plug patterns fill the plug contact holes, respectively. One of the plug contact holes is disposed on the main surface of the semiconductor substrate, and the remaining plug contact holes extend downward from the main surface of the semiconductor substrate and are aligned in parallel with the channel-portion hole.

According to some embodiments of the invention, there is provided DRAM cells having plug contact holes extending downward from a main surface of a semiconductor substrate that includes an active region isolated by a device isolation layer. At least two channel-portion holes are disposed in a semiconductor substrate of the active region. First word line patterns fill the channel-portion holes and are disposed in parallel and being spaced apart from each other on the active region. Second word line patterns are disposed on the device isolation layer. The second word line patterns are adjacent to the active region respectively and disposed in parallel and opposite to at least one of the first word line patterns. Plug contact holes are disposed between the first and the second word line patterns. Each plug contact hole is disposed to extend from an upper surface of each of the first and the second word line patterns and isolated by an interlayer insulating layer. Plug patterns fill the plug contact holes, respectively. Each of the plug contact holes extends downward from a main surface of the semiconductor substrate and is aligned in parallel with the channel-portion holes.

According to other embodiments of the invention, there is provided DRAM cells having plug contact holes extending downward from a main surface of a semiconductor substrate that include an active region isolated by a device isolation layer. At least two channel-portion holes are disposed in a semiconductor substrate of the active region. First word line patterns fill the channel-portion holes and are disposed in parallel and spaced apart from each other on the active region. Second word line patterns are disposed on the device isolation layer. The second word line patterns are adjacent to the active region respectively and disposed in parallel and opposite to at least one of the first word line patterns. Plug contact holes are disposed between the first and the second word line patterns. Each plug contact hole is disposed to extend from an upper surface of each of the first and the second word line patterns and isolated by an interlayer insulating layer. Plug patterns fill the plug contact holes, respectively. At this time, at least one of the plug contact holes is disposed on a main surface of the semiconductor substrate, and the remaining plug contact holes extend downward from a main surface of the semiconductor substrate and are aligned in parallel with the channel-portion holes.

According to some embodiments of the invention, there is provided a method of forming semiconductor devices having plug contact holes extending downward from a main surface of a semiconductor substrate that includes forming a channel-portion hole in a semiconductor substrate. A word line pattern is formed to fill the channel-portion hole on the semiconductor substrate. An interlayer insulating layer covers the word line pattern. Plug contact holes are respectively formed on both sidewalls of the word line pattern to penetrate the interlayer insulating layer. The plug contact holes are formed to extend downward from a main surface of the semiconductor substrate and be aligned in parallel with the channel-portion hole. Plug patterns are respectively formed to fill the plug contact holes.

According to some embodiments of the invention, there is provided a method of forming semiconductor devices having plug contact holes extending downward from a main surface of a semiconductor substrate that includes forming a channel-portion hole in a semiconductor substrate. Word line patterns are formed to fill the channel-portion hole on the semiconductor substrate. An interlayer insulating layer covers the word line pattern. Plug contact holes are respectively formed on both sidewalls of the word line pattern to penetrate the interlayer insulating layer. One of the plug contact holes is formed on a main surface of the semiconductor substrate, and the remaining plug contact holes are formed to extend downward from the main surface of the semiconductor substrate, and aligned in parallel with the channel-portion hole. Plug patterns are formed to fill the plug contact holes, respectively.

According to some embodiments of the invention, there is provided a method of forming DRAM cells having plug contact holes extending downward from a main surface of a semiconductor substrate that includes forming an active region isolated by a device isolation layer. At least two channel-portion holes are disposed in a semiconductor substrate of the active region. First and second word line patterns are respectively formed on the active region and the device isolation layer. The second word line patterns are formed in parallel and opposite to at least one of the first word line patterns, and concurrently the first word line patterns are respectively formed to fill the channel-portion holes. An interlayer insulating layer covers the first and the second word line patterns. Plug contact holes are respectively formed between the first and the second word line patterns to penetrate the interlayer insulating layer. The plug contact holes are formed to extend downward from a main surface of the semiconductor substrate, being aligned in parallel with the channel-portion holes. Plug patterns are formed to fill the plug contact holes, respectively.

According to other embodiments of the invention, there is provided a method of forming DRAM cells having plug contact holes extending downward from a main surface of a semiconductor substrate that includes forming an active region isolated by a device isolation layer. At least two channel-portion holes are disposed in a semiconductor substrate of the active region. First and second word line patterns are respectively formed on the active region and the device isolation layer. The second word line patterns are formed in parallel and opposite to at least one of the first word line patterns, and concurrently the first word line patterns are respectively formed to fill the channel-portion holes. An interlayer insulating layer covers the first and the second word line patterns. Plug contact holes are respectively formed between the first and the second word line patterns to penetrate the interlayer insulating layer. At least one of the plug contact holes is formed on a main surface of the semiconductor substrate, and the remaining plug contact holes are formed to extend downward from the main surface of the semiconductor substrate and be aligned in parallel with the channel-portion holes. Plug patterns are formed to fill the plug contact holes, respectively.

Although the invention has been described with reference to the preferred embodiments thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

1. A semiconductor device comprising:
a channel-portion hole disposed in a semiconductor substrate;
word line patterns that fill the channel-portion hole, and disposed on a main surface of the semiconductor substrate;
plug contact holes disposed respectively on both sidewalls of the word line patterns, each plug contact hole extending from an upper surface of the word line patterns, and isolated by an interlayer insulating layer; and
plug patterns that respectively fill the plug contact holes, in which the plug contact holes extend downward from a main surface of the semiconductor substrate and are aligned with the channel-portion hole.

2. The semiconductor device according to claim 1, wherein the plug contact holes have the same depth.

3. The semiconductor device according to claim 1, wherein the plug contact holes have different depths from each other.

4. The semiconductor device according to claim 1, further comprising a metal silicide layer disposed between the plug patterns and the semiconductor substrate.

5. The semiconductor device according to claim 1, further comprising a word line insulating layer pattern disposed between the word line patterns and the channel-portion hole.

6. The semiconductor device according to claim 1, further comprising word line spacers respectively disposed on sidewalls of the word line patterns.

7. The semiconductor device according to claim 1, further comprising electrode impurity regions disposed in the semiconductor substrate and respectively surrounding lower portions of the plug patterns, and overlapping the word line patterns.

8. The semiconductor device according to claim 1, further comprising a channel region surrounding a lower portion of the channel-portion hole.

9. A semiconductor device comprising:
a channel-portion hole disposed in a semiconductor substrate;
word line patterns that fill the channel-portion hole, and disposed on a main surface of the semiconductor substrate;
plug contact holes disposed respectively on both sidewalls of the word line patterns, each plug contact hole extending from an upper surface of the word line patterns, and isolated by an interlayer insulating layer; and
plug patterns that respectively fill the plug contact holes, in which one of the plug contact holes is disposed on the main surface of the semiconductor substrate, and the remaining plug contact holes extend downward from the main surface of the semiconductor substrate and are in parallel with the channel-portion hole.

10. The semiconductor device according to claim 9, further comprising a metal silicide layer disposed between the plug patterns and the semiconductor substrate.

11. The semiconductor device according to claim 9, further comprising a word line insulating layer pattern disposed between the word line patterns and the channel-portion hole.

12. The semiconductor device according to claim 9, further comprising word line spacers respectively disposed on sidewalls of the word line patterns.

13. The semiconductor device according to claim 9, further comprising electrode impurity regions disposed in the semiconductor substrate and respectively surrounding lower portions of the plug patterns, and overlapping the word line patterns.

14. The semiconductor device according to claim 9, further comprising a channel region surrounding a lower portion of the channel-portion hole.

15. A DRAM cell comprising:
an active region isolated by a device isolation layer formed on a semiconductor substrate;
at least two channel-portion holes disposed in the active region;
first word line patterns filling the channel-portion holes, and disposed in parallel and being spaced apart from each other on the active region;
second word line patterns disposed on the device isolation layer, the second word line patterns being adjacent to the active region, and disposed in parallel and opposite to at least one of the first word line patterns;
plug contact holes disposed between the first and the second word line patterns, each plug contact hole extending from an upper surface of each of the first and the second word line patterns, and isolated by an interlayer insulating layer; and
plug patterns respectively filling the plug contact holes, wherein each of the plug contact holes extends downward from a main surface of the semiconductor substrate and is aligned with the channel-portion holes.

16. The DRAM cell according to claim 15, wherein the plug contact holes have the same depth.

17. The DRAM cell according to claim 15, wherein the plug contact holes have different depths from each other.

18. The DRAM cell according to claim 15, further comprising a metal silicide layer disposed between the plug patterns and the semiconductor substrate.

19. The DRAM cell according to claim 15, further comprising a word line insulating layer pattern disposed between the first word line patterns and the channel-portion holes.

20. The DRAM cell according to claim 15, further comprising word line spacers respectively disposed on sidewalls of the first and the second word line patterns.

21. The DRAM cell according to claim 15, further comprising electrode impurity regions disposed in the semiconductor substrate and respectively surrounding lower portions of the plug patterns, and overlapping the first and the second word line patterns.

22. The DRAM cell according to claim 15, further comprising a channel region surrounding lower portions of the channel-portion holes.

23. A DRAM cell comprising:
an active region isolated by a device isolation layer on a semiconductor substrate;
at least two channel-portion holes disposed in the active region;
first word line patterns filling the channel-portion holes, and disposed in parallel and being spaced apart from each other on the active region;
second word line patterns disposed on the device isolation layer, the second word line patterns being adjacent to the active region, and disposed in parallel and opposite to at least one of the first word line patterns;
plug contact holes disposed between the first and the second word line patterns, each plug contact hole extending from an upper surface of each of the first and the second word line patterns, and isolated by an interlayer insulating layer; and
plug patterns respectively filling the plug contact holes, in which
at least one of the plug contact holes is disposed on a main surface of the semiconductor substrate, and the remaining plug contact holes extend downward from a main surface of the semiconductor substrate and are aligned in parallel with the channel-portion holes.

24. The DRAM cell according to claim 23, further comprising a metal silicide layer disposed between the plug patterns and the semiconductor substrate.

25. The DRAM cell according to claim 23, further comprising a word line insulating layer pattern disposed between the first and the second word line patterns and the channel-portion holes.

26. The DRAM cell according to claim 23, further comprising word line spacers respectively disposed on sidewalls of the first and the second word line patterns.

27. The DRAM cell according to claim 23, further comprising electrode impurity regions disposed in the semiconductor substrate and respectively surrounding lower portions of the plug patterns, and overlapping the first and the second word line patterns.

28. The DRAM cell according to claim 23, further comprising a channel region surrounding lower portions of the channel-portion holes.

29. A method of forming a semiconductor device, the method comprising:
forming a channel-portion hole in a semiconductor substrate;
forming a word line pattern that fills the channel-portion hole on the semiconductor substrate;
forming an interlayer insulating layer that covers the word line pattern;
forming plug contact holes respectively on both sidewalls of the word line pattern to penetrate the interlayer insulating layer, the plug contact holes being formed to extend downward from a main surface of the semiconductor substrate, and being formed to be aligned in parallel with the channel-portion hole; and
forming plug patterns that respectively fill the plug contact holes.

30. The method according to claim 29, further comprising, before forming the channel-portion hole, performing an ion implantation process in the semiconductor substrate to form a channel region, in which the channel-portion hole is formed to contact the channel region.

31. The method according to claim 29, wherein the forming the channel-portion hole comprises:
sequentially forming pad layer patterns and photoresist patterns on the semiconductor substrate; and
performing an etching process in the semiconductor substrate, using the photoresist patterns and the pad layer patterns as an etching mask.

32. The method according to claim 29, further comprising, before forming the word line pattern, conformably forming a word line insulating layer pattern along the channel-portion hole.

33. The method according to claim 29, further comprising, before forming the interlayer insulating layer, forming word line spacers respectively on sidewalls of the word line pattern.

34. The method according to claim 29, further comprising, before forming the interlayer insulating layer, forming electrode impurity regions in the semiconductor substrate to respectively overlap the word line pattern, in which the electrode impurity regions are formed to surround lower portions of the plug patterns.

35. The method according to claim 29, further comprising, before forming the plug patterns, forming metal silicide layers respectively on bottoms of the plug contact holes.

36. The method according to claim 29, wherein the plug contact holes are formed to have the same depth.

37. The method according to claim 29, wherein the plug contact holes are formed to have different depths from each other.

38. A method of forming a semiconductor device, the method comprising:
forming a channel-portion hole in a semiconductor substrate;
forming a word line pattern that fills the channel-portion hole on the semiconductor substrate;
forming an interlayer insulating layer that covers the word line pattern;
forming plug contact holes respectively on both sidewalls of the word line pattern to penetrate the interlayer insulating layer, one of the plug contact holes being formed on a main surface of the semiconductor substrate, and the remaining plug contact holes formed to extend downward from the main surface of the semiconductor substrate, and aligned with the channel-portion hole; and
forming plug patterns that respectively fill the plug contact holes.

39. The method according to claim 38, further comprising, before forming the channel-portion hole, performing an ion implantation process in the semiconductor substrate to form a channel region, in which the channel-portion hole is formed to contact the channel region.

40. The method according to claim 38, wherein the forming the channel-portion hole comprises:
sequentially forming pad layer patterns and photoresist patterns on the semiconductor substrate; and
performing an etching process in the semiconductor substrate, using the photoresist patterns and the pad layer patterns as an etching mask.

41. The method according to claim 38, further comprising, before forming the word line pattern, conformably forming a word line insulating layer pattern along the channel-portion hole.

42. The method according to claim 38, further comprising, before forming the interlayer insulating layer, forming word line spacers respectively on sidewalls of the word line pattern.

43. The method according to claim 38, further comprising, before forming the interlayer insulating layer, forming electrode impurity regions in the semiconductor substrate to overlap the word line pattern, in which the electrode impurity regions are formed to surround lower portions of the plug patterns.

44. The method according to claim 38, further comprising, before forming the plug patterns, forming metal silicide layers respectively on bottoms of the plug contact holes.

45. A method of forming a DRAM cell comprising:
forming an active region isolated by a device isolation layer;
forming at least two channel-portion holes disposed in a semiconductor substrate of the active region;
forming first and second word line patterns respectively on the active region and the device isolation layer, the second word line patterns being formed in parallel and opposite to at least one of the first word line patterns, and the first word line patterns being respectively formed to fill the channel-portion holes;
forming an interlayer insulating layer that covers the first and the second word line patterns;
forming plug contact holes respectively between the first and the second word line patterns to penetrate the interlayer insulating layer, the plug contact holes formed to extend downward from a main surface of the semiconductor substrate, and aligned with the channel-portion holes; and
forming plug patterns that respectively fill the plug contact holes.

46. The method according to claim 45, further comprising, before forming the channel-portion holes, performing an ion implantation process in the semiconductor substrate to form a channel region, in which the channel-portion holes are formed to contact the channel region.

47. The method according to claim 45, wherein the forming channel-portion holes comprises:
sequentially forming pad layer patterns and photoresist patterns on the semiconductor substrate; and
performing an etching process on the semiconductor substrate, using the photoresist patterns and the pad layer patterns as an etching mask.

48. The method according to claim 45, further comprising, before forming the first and the second word line patterns, conformably forming word line insulating layer patterns along the channel-portion holes.

49. The method according to claim 45, further comprising, before forming the interlayer insulating layer, forming word line spacers respectively on sidewalls of the first and the second word line patterns.

50. The method according to claim 45, further comprising, before forming the interlayer insulating layer, forming electrode impurity regions in the semiconductor substrate to respectively overlap the first and the second word line patterns, in which the electrode impurity regions are formed to surround lower portions of the plug patterns.

51. The method according to claim 45, wherein the plug contact holes are formed to have the same depth.

52. The method according to claim 45, wherein the plug contact holes are formed to have different depths from each other.

53. The method according to claim 45, further comprising, before forming the plug patterns, forming metal silicide layers respectively on bottoms of the plug contact holes.

54. A method of forming a DRAM cell comprising:
forming an active region isolated by a device isolation layer;
forming at least two channel-portion holes disposed in a semiconductor substrate of the active region;
forming first and second word line patterns respectively on the active region and the device isolation layer, the second word line patterns being formed in parallel and opposite to at least one of the first word line patterns, and the first word line patterns being respectively formed to fill the channel-portion holes;
forming an interlayer insulating layer that covers the first and the second word line patterns;
forming plug contact holes respectively between the first and the second word line patterns to penetrate the interlayer insulating layer, at least one of the plug contact holes being formed on a main surface of the semiconductor substrate, remaining plug contact holes being formed to extend downward from the main surface of the semiconductor substrate, and being aligned in parallel with the channel-portion holes; and
forming plug patterns that respectively fill the plug contact holes.

55. The method according to claim 54, further comprising, before forming the channel-portion holes, performing an ion implantation process in the semiconductor substrate to form a channel region, in which the channel-portion holes are formed to contact the channel region.

56. The method according to claim 54, wherein the forming channel-portion holes comprises:
sequentially forming pad layer patterns and photoresist patterns on the semiconductor substrate; and
performing an etching process on the semiconductor substrate using the photoresist patterns and the pad layer patterns as an etching mask.

57. The method according to claim 54, further comprising, before forming the first and the second word line patterns, conformably forming word line insulating layer patterns along the channel-portion holes.

58. The method according to claim 54, further comprising, before forming the interlayer insulating layer, forming word line spacers respectively on sidewalls of the first and the second word line patterns.

59. The method according to claim 54, further comprising, before forming the interlayer insulating layer, forming electrode impurity regions in the semiconductor substrate to respectively overlap the first and the second word line patterns, in which the electrode impurity regions are formed to surround lower portions of the plug patterns.

60. The method according to claim 54, further comprising, before forming the plug patterns, forming metal silicide layers respectively on bottoms of the plug contact holes.
